(19) United States
(12) Patent Application Publication
(10) Pub. No.: US 2023/0087049 A1
(43) Pub. Date: Mar. 23, 2023

(54) BULK ACOUSTIC RESONATOR

(71) Applicant: SAMSUNG ELECTRO-MECHANICS CO., LTD., Suwon-si (KR)

(72) Inventors: Tae Kyung LEE, Suwon-si (KR); Sang Heon HAN, Suwon-si (KR); Kwang Su KIM, Suwon-si (KR); Sung Joon PARK, Suwon-si (KR); Jae Goon AUM, Suwon-si (KR)

(73) Assignee: SAMSUNG ELECTRO-MECHANICS CO., LTD., Suwon-si (KR)

(21) Appl. No.: 17/689,333

(22) Filed: Mar. 8, 2022

(30) Foreign Application Priority Data
Sep. 13, 2021 (KR) 10-2021-0121719

(51) Int. Cl. H03H 9/02; H03H 9/17

(52) U.S. Cl. CPC H03H 9/02118; H03H 9/174

(57) ABSTRACT

A bulk acoustic resonator includes: a substrate; a protective layer; and a resonant portion including a piezoelectric layer, a first electrode disposed between the piezoelectric layer and the substrate, and a second electrode disposed between the piezoelectric layer and the protective layer. The protective layer covers a central portion of the resonant portion and a reflective portion surrounding the central portion and formed in a region in which an upper surface of the second electrode rises relative to the central portion. An upper surface of a portion of the protective layer covering the reflective portion is more gently inclined than the upper surface of a portion of the second electrode in the reflective portion.

### CROSS-REFERENCE TO RELATED APPLICATIONS

This application claims the benefit under 35 U.S.C. §119(a) of Korean Patent Application No. 10-2021-0121719 filed on Sep. 13, 2021 in the Korean Intellectual Property Office, the entire disclosure of which is incorporated herein by reference for all purposes.

### BACKGROUND

### 1. Field

The following description relates to a bulk acoustic resonator.

### 2. Description of Related Art

Recently, with the rapid development of mobile communications devices, chemical and biological testing devices, etc., demand for small and lightweight filters, oscillators, resonant elements, and acoustic resonant mass sensors used in such devices has increased.

Acoustic resonators such as bulk acoustic wave (BAW) resonators may be configured as a means for implementing such small and lightweight filters, oscillators, resonator elements, acoustic resonant mass sensors, and the like, and may have a very small size and good performance, compared to dielectric filters, metal cavity filters, and waveguides. Therefore, acoustic resonators have been widely used in communications modules of modern mobile devices requiring good performance (e.g., a wide pass bandwidth).

Recently, interest has increased in technology for communications having a higher frequency or a wider bandwidth, such as sub-6 GHz (e.g., 4 to 6 GHz) 5G communications. Development of bulk acoustic resonator technology that may be implemented in a candidate band of such higher frequency or wider bandwidth communications is desired.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic resonator includes: a substrate; a protective layer; and a resonant portion including a piezoelectric layer, a first electrode disposed between the piezoelectric layer and the substrate, and a second electrode disposed between the piezoelectric layer and the protective layer. The protective layer covers a central portion of the resonant portion and a reflective portion surrounding the central portion and formed in a region in which an upper surface of the second electrode rises relative to the central portion. An upper surface of a portion of the protective layer covering the reflective portion is more gently inclined than the upper surface of a portion of the second electrode in the reflective portion.

The protective layer may include any one or any combination of any two or more of SiO2, Si3N4, Al2O3, and AIN, or includes a piezoelectric material included in the piezoelectric layer.

A specific acoustic impedance of the protective layer may be lower than a specific acoustic impedance of the second electrode. An acoustic impedance of a combination structure of the resonant portion and the protective layer in the reflective portion may be higher than an acoustic impedance of the combination structure in the central portion.

The upper surface of the portion of the protective layer covering the reflective portion in the protective layer may rise relative to a portion of the protective layer covering the central portion.

The protective layer may continuously cover the reflective portion and an outer portion disposed outside of the reflective portion. The second electrode may not be disposed at the outer portion.

The upper surface of the portion of the second electrode in the reflective portion and a lower surface of the portion of the second electrode in the reflective portion may be slanted with respect to an upper surface of a portion of the second electrode in the central portion and a lower surface of a portion of the second electrode in the central portion.

The upper surface of the portion of the second electrode in the reflective portion may rise as a distance between the first electrode and the second electrode increases.

The bulk acoustic resonator may further include an insertion layer partially disposed in the resonant portion. The upper surface of the portion of the second electrode in the reflective portion may rise as at least a part of the piezoelectric layer and the second electrode is uplifted by the insertion layer.

A thickness of the portion of the protective layer covering the reflective portion may be less than a thickness of a portion of the protective layer covering the central portion.

In another general aspect, a bulk acoustic resonator includes: a substrate; a protective layer; and a resonant portion including a piezoelectric layer, a first electrode disposed between the piezoelectric layer and the substrate, and a second electrode disposed between the piezoelectric layer and the protective layer. The protective layer covers a central portion of the resonant portion and a reflective portion extending a spacing distance between the first electrode and the second electrode, relative to the central portion, and surrounding the central portion. A thickness of a portion of the protective layer covering the reflective portion is less than a thickness of a portion of the protective layer covering the central portion.

The bulk acoustic resonator may further include an insertion layer partially disposed in the resonant portion. An upper surface of a portion of the second electrode in the reflective portion may rise as at least a portion of the piezoelectric layer and the second electrode is uplifted by the insertion layer.

The protective layer may continuously cover the reflective portion and an outer portion disposed outside of the reflective portion. A thickness of the portion of the protective layer covering the reflective portion may be less than a thickness of a portion of the protective layer covering the outer portion.

An upper surface of the portion of the protective layer covering the reflective portion may rise relative to an upper surface of the portion of the protective layer covering the central portion.

A ratio of a thickness of the portion of the protective layer covering the reflective portion to a thickness of the portion of the protective layer covering the central portion may be less than a ratio of a thickness of the second electrode in the reflective portion to a thickness of the second electrode in the central portion.

The thickness of the portion of the protective layer covering the reflective portion may be less than a thickness of the portion of the protective layer covering the central portion, such that a difference between a resonance frequency and an antiresonance frequency of the bulk acoustic resonator is increased.

The protective layer may include any one or any combination of any two or more of SiO2, Si3N4, Al2O3, and AIN or may include a piezoelectric material included in the piezoelectric layer.

In another general aspect, a bulk acoustic resonator includes: a substrate; a protective layer; and a resonant portion including a piezoelectric layer, a first electrode disposed between the piezoelectric layer and the substrate, and a second electrode disposed between the piezoelectric layer and the protective layer. The protective layer covers a central portion of the resonant portion and a reflective portion surrounding the central portion and formed in a region in which an upper surface of the second electrode is elevated relative to the central portion. An upper surface of a portion of the protective layer covering the reflective portion is inclined less than the upper surface of a portion of the second electrode in the reflective portion, and a thickness of the portion of the protective layer covering the reflective portion is less than each of a thickness of a portion of the protective layer covering the central portion and a thickness of a portion of the protective layer covering an outer portion of the bulk acoustic resonator disposed outside of the reflective portion.

A ratio of a thickness of the portion of the protective layer covering the reflective portion to a thickness of the portion of the protective layer covering the central portion may be less than a ratio of a thickness of the second electrode in the reflective portion to a thickness of the second electrode in the central portion.

A specific acoustic impedance of a material of the protective layer may be lower than a specific acoustic impedance of a material of the second electrode.

The second electrode may not be disposed in the outer portion.

Other features and aspects will be apparent from the following detailed description, the drawings, and the claims.

### BRIEF DESCRIPTION OF DRAWINGS

FIG. 1 is a plan view of a bulk acoustic resonator, according to an embodiment.

FIG. 2 is a cross-sectional view taken along line I-I' of FIG. 1.

FIG. 3 is a cross-sectional view taken along line II-II' of FIG. 1.

FIG. 4 is a cross-sectional view taken along line III-III' of FIG. 1.

FIG. 5 is a cross-sectional view and a photograph illustrating a structure for increasing lateral wave reflection performance of a bulk acoustic resonator, according to an embodiment.

FIG. 6 is a diagram illustrating specific acoustic impedances of materials that may be included in a protective layer and materials that may be included in an electrode.

FIGS. 7 and 8 are cross-sectional views illustrating modified structures of a second electrode of a bulk acoustic resonator, according to embodiments.

FIG. 9 is a perspective view illustrating a filter including a bulk acoustic resonator, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

Herein, it is to be noted that use of the term “may” with respect to an embodiment or example, e.g., as to what an embodiment or example may include or implement, means that at least one embodiment or example exists in which such a feature is included or implemented while all examples and examples are not limited thereto.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element’s relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

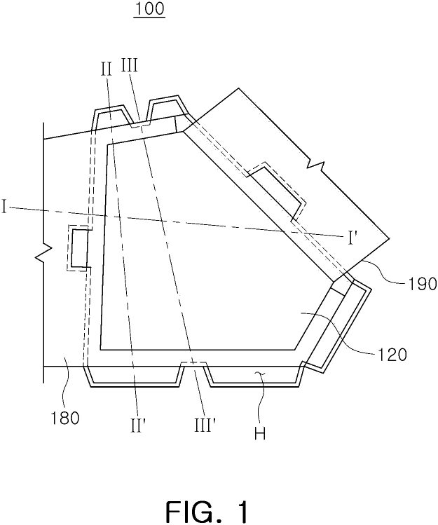

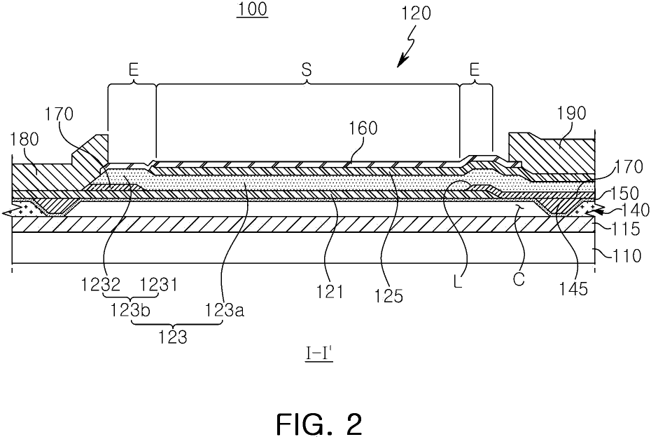

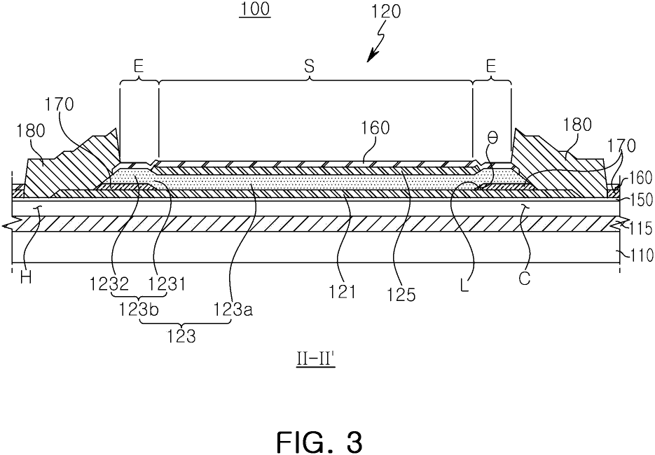

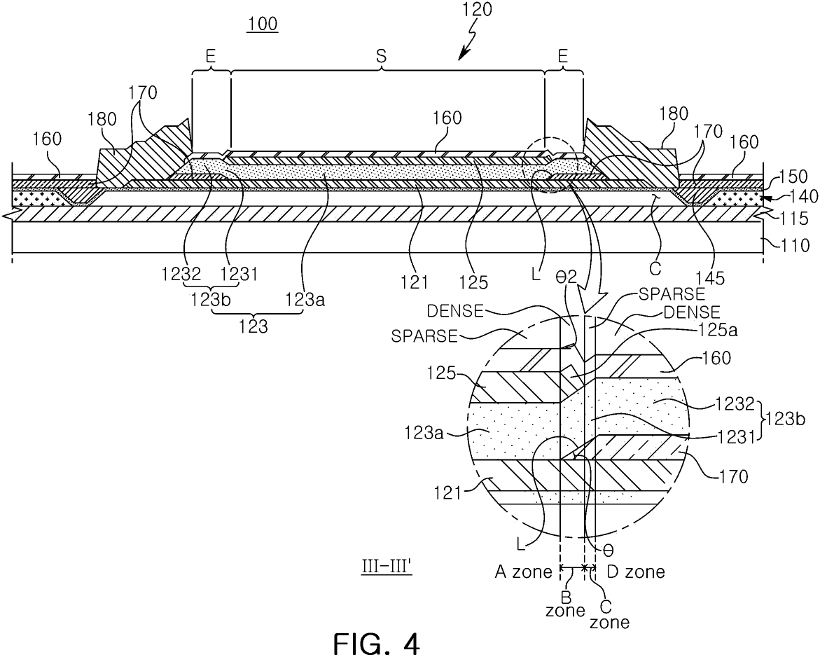

FIG. 1 is a plan view of a bulk acoustic resonator, according to an embodiment. FIG. 2 is a cross-sectional view taken along line I-I' of FIG. 1. FIG. 3 is a cross-sectional view taken along line II-II' of FIG. 1. FIG. 4 is a cross-sectional view taken along line III-III' of FIG. 1.

Referring to FIGS. 1 to 4, a bulk acoustic resonator 100, according to an embodiment, may include a substrate 110, a resonant portion 120, and a protective layer 160.

The substrate 110 may be a silicon substrate. For example, a silicon wafer or a silicon on insulator (SOI) type substrate may be used as the substrate 110.

An insulating layer 115 may be disposed on an upper surface of the substrate 110 to electrically isolate the substrate 110 and the resonant portion 120. In addition, the insulating layer 115 may prevent the substrate 110 from being etched by an etching gas when a cavity C is formed during a manufacturing process of the bulk acoustic resonator.

In this case, the insulating layer 115 may be formed of any one or any combination of any two or more of silicon dioxide (SiO₂), silicon nitride (Si₃N₄), aluminum oxide (Al₂O₃), and aluminum nitride (AIN), and may be formed through any one of processes among chemical vapor deposition, RF magnetron sputtering, and evaporation.

A sacrificial layer 140 may be formed on the insulating layer 115, and a cavity C and an etch stop portion 145 may be disposed inside the sacrificial layer 140. The cavity C may be formed as an empty space (e.g., an air cavity) and may be formed by removing a portion of the sacrificial layer 140. Since the cavity C is formed inside the sacrificial layer 140, the resonant portion 120 formed on the sacrificial layer 140 may be formed to be flat as a whole.

The etch stop portion 145 may be disposed along a boundary of the cavity C. Since the etch stop portion 145 may be provided to prevent etching from proceeding beyond the cavity region during the cavity C formation process, the etch stop portion 145 may contain the same material as that of the insulating layer 115, but is not limited thereto.

A membrane layer 150 is formed on the sacrificial layer 140 and may form an upper surface of the cavity C. Accordingly, the membrane layer 150 may also be formed of a material that is not easily removed in the process of forming the cavity C.

For example, when a halide-based etching gas such as fluorine (F) or chlorine (Cl) is used to remove a portion (e.g., the cavity region) of the sacrificial layer 140, the membrane layer 150 may be formed of a material having low reactivity with the etching gas. In this case, the membrane layer 150 may include either one or both of silicon dioxide (SiO₂) and silicon nitride (Si₃N₄).

In addition, the membrane layer 150 may be formed of a dielectric layer including any one or any combination of any two or more of magnesium oxide (MgO), zirconium oxide (ZrO₂), aluminum nitride (AIN), lead zirconate titanate (PZT), gallium arsenide (GaAs), hafnium oxide (HfO₂), aluminum oxide (Al₂O₃), titanium oxide (TiO₂), and zinc oxide (ZnO) or may be formed of a metal layer including at least one of aluminum (Al), nickel (Ni), chromium (Cr), platinum (Pt), gallium (Ga), and hafnium (Hf).

The resonant portion 120 includes, for example, a first electrode 121, a piezoelectric layer 123, and a second electrode 125. In the resonant portion 120, the first electrode 121, the piezoelectric layer 123, and the second electrode 125 are sequentially stacked from the bottom. Accordingly, in the resonant portion 120, the piezoelectric layer 123 is disposed between the first electrode 121 and the second electrode 125.

Since the resonant portion 120 is formed on the membrane layer 150, the membrane layer 150, the first electrode 121, the piezoelectric layer 123, and the second electrode 125 may be sequentially stacked on the substrate 110 to form the resonant portion 120.

The resonant portion 120 may cause resonance based on the piezoelectric layer 123 according to a frequency of a radio frequency (RF) signal applied to the first electrode 121 and the second electrode 125, may allow the RF signal to particularly easily pass through in one of a resonant frequency and an antiresonant frequency, and may properly block the RF signal in the other of the resonant frequency and the antiresonant frequency.

The resonant portion 120 may include a central portion S, in which the first electrode 121, the piezoelectric layer 123, and the second electrode 125 are substantially flatly stacked, and an expansion portion E, in which an insertion layer 170 is disposed between the first electrode 121 and the piezoelectric layer 123.

The central portion S is a region disposed at the center of the resonant portion 120 and the expansion portion E is a region disposed along a circumference of the central portion S. Therefore, the expansion portion E is a region extending outwardly from the central portion S and is a region formed in a continuous ring shape along the circumference of the central portion S. However, if necessary, a portion of the expansion portion E may be formed in a discontinuous ring shape.

Accordingly, as illustrated in FIG. 2, in a cross-section of the resonant portion 120 taken to cross the central portion S, expansion portions E are disposed at both ends of the central portion S. In addition, the insertion layer 170 may be disposed on both sides of the expansion portions E disposed at both ends of the central portion S.

The insertion layer 170 may have an inclined surface L having a thickness increasing in a direction away from the central portion S.

In the expansion portion E, the piezoelectric layer 123 and the second electrode 125 are disposed on the insertion layer 170. Accordingly, portions of the piezoelectric layer 123 and the second electrode 125 positioned in the expansion portion E may have inclined surfaces along a shape of the insertion layer 170.

Meanwhile, since the expansion portion E may be defined to be included in the resonant portion 120, resonance may also be made in the expansion portion E. However, the disclosure herein is not limited to such a configuration, and resonance may not occur in the expansion portion E and may be made only in the central portion S.

The first electrode 121 and the second electrode 125 may be formed of a conductor, for example, gold, molybdenum, ruthenium, iridium, aluminum, platinum, titanium, tungsten, palladium, tantalum, chromium, nickel, or a metal including any one or any combination of any two or more of gold, molybdenum, ruthenium, iridium, aluminum, platinum, titanium, tungsten, palladium, tantalum, chromium, and nickel, but is not limited thereto.

In the resonant portion 120, the first electrode 121 is formed to have an area larger than that of the second electrode 125, and a first metal layer 180 is disposed on an outer portion of the first electrode 121. Accordingly, the first metal layer 180 may be disposed to be spaced apart from the second electrode 125 by a predetermined distance and may be disposed to surround the resonant portion 120.

Since the first electrode 121 is disposed on the membrane layer 150, the first electrode 121 is formed to be flat as a whole. Meanwhile, since the second electrode 125 is disposed on the piezoelectric layer 123, the second electrode 125 may include a bent portion corresponding to a shape of the piezoelectric layer 123.

The second electrode 125 may be disposed throughout an entirety of the central portion S and may be partially disposed in the expansion portion E. Accordingly, the second electrode 125 may include a portion disposed on a piezoelectric portion 123a of the piezoelectric layer 123, which will be described later, and a portion disposed on a bent portion 123b of the piezoelectric layer 123.

More specifically, in an embodiment, the second electrode 125 may be disposed to cover the entire piezoelectric portion 123a and a portion of an inclined portion 1231 of the piezoelectric layer 123. Accordingly, the portion of the second electrode (125a in FIG. 4) disposed in the expansion portion E has an area smaller than that of an inclined surface of the inclined portion 1231, and in the resonant portion 120, the second electrode 125 is formed to have an area smaller than that of the piezoelectric layer 123.

Accordingly, as illustrated in FIG. 2, in the cross-section of the resonant portion 120 taken to cross the central portion S, the end of the second electrode 125 is disposed in the expansion portion E. In addition, the end of the second electrode 125 disposed in the expansion portion E is disposed such that at least a portion thereof overlaps the insertion layer 170. Here, the overlap is a configuration in which, when the second electrode 125 is projected onto a plane on which the insertion layer 170 is disposed, a shape of the second electrode 125 projected on the plane overlaps a shape of the insertion layer 170.

Each of the first electrode 121 and the second electrode 125 may be used as either one of an input electrode and an output electrode for inputting and outputting an electrical signal such as a radio frequency (RF) signal. That is, when the first electrode 121 is used as an input electrode, the second electrode 125 may be used as an output electrode, and when the first electrode 121 is used as an output electrode, the second electrode 125 may be used as an input electrode.

As illustrated in FIG. 4, when the end of the second electrode 125 is positioned on the inclined portion 1231 of the piezoelectric layer 123 to be described in more detail later, in the case of acoustic impedance of the resonant portion 120, a local structure is formed as a sparse-dense-sparse-dense structure from the central portion S, and thus, a reflective interface reflecting a lateral wave toward the inside of the resonant portion 120 increases. Accordingly, since most of the lateral waves cannot escape to the outside of the resonant portion 120 but are reflected into the resonant portion 120, the performance of the acoustic resonator 100 may be improved.

The piezoelectric layer 123 is a portion producing a piezoelectric effect that converts electrical energy into mechanical energy in the form of acoustic waves, and is formed on the first electrode 121 and the insertion layer 170 to be described in more detail later.

Zinc oxide (ZnO), aluminum nitride (AIN), doped aluminum nitride, lead zirconate titanate, quartz, etc. may be selectively used as a material of the piezoelectric layer 123. The doped aluminum nitride may further include a rare earth metal, a transition metal, or an alkaline earth metal. The rare earth metal may include any one or any combination of any two or more of scandium (Sc), erbium (Er), yttrium (Y), and lanthanum (La). The transition metal may include any one or any combination of any two or more of hafnium (Hf), titanium (Ti), zirconium (Zr), tantalum (Ta), and niobium (Nb). The alkaline earth metal may also include magnesium (Mg). For example, the content of elements doped into aluminum nitride (AIN) of the piezoelectric layer 123 may range from 0.1 to 30 at%. The element doped into aluminum nitride (AIN) may be scandium (Sc). Accordingly, a piezoelectric constant of the piezoelectric layer 123 may be increased, and Kₜ² of the acoustic resonator may be increased.

For example, the piezoelectric layer 123 may include the piezoelectric portion 123a disposed in the central portion S and the bent portion 123b disposed in the expansion portion E.

The piezoelectric portion 123a is a portion directly stacked on an upper surface of the first electrode 121. Accordingly, the piezoelectric portion 123a is interposed between the first electrode 121 and the second electrode 125 to form a flat shape together with the first electrode 121 and the second electrode 125.

The bent portion 123b may be a region extending outwardly from the piezoelectric portion 123a and positioned in the expansion portion E.

The bent portion 123b is disposed on the insertion layer 170 and is formed such that an upper surface of the bent portion 123b rises according to a shape of the insertion layer 170. Accordingly, the piezoelectric layer 123 is bent at a boundary between the piezoelectric portion 123a and the bent portion 123b, and the bent portion 123b rises to correspond to a thickness and shape of the insertion layer 170.

The bent portion 123b may include an inclined portion 1231 and an extension portion 1232.

The inclined portion 1231 is a portion formed to be inclined along an inclined surface L of the insertion layer 170, which will be described later. Also, the extension portion 1232 is a portion extending outwardly from the inclined portion 1231.

The inclined portion 1231 may be formed parallel to the inclined surface L of the insertion layer 170, and an inclination angle of the inclined portion 1231 may be the same as an inclination angle of the inclined surface L of the insertion layer 170.

The insertion layer 170 is disposed on a surface formed by the membrane layer 150, the first electrode 121, and the etch stop portion 145. Accordingly, the insertion layer 170 is partially disposed in the resonant portion 120 and disposed between the first electrode 121 and the piezoelectric layer 123.

The insertion layer 170 is disposed around the central portion S to support the bent portion 123b of the piezoelectric layer 123. Accordingly, the bent portion 123b of the piezoelectric layer 123 may be divided into the inclined portion 1231 and the extension portion 1232 according to the shape of the insertion layer 170.

In this embodiment, the insertion layer 170 is disposed in a region except for the central portion S. For example, the insertion layer 170 may be disposed in the entire region except for the central portion S on the substrate 110 or may be disposed in a partial region.

The insertion layer 170 is formed to have a thickness increasing in a direction away from the central portion S. Due to this configuration, a side surface of the insertion layer 170 disposed adjacent to the central portion S is formed as the inclined surface L having a certain inclination angle θ. For example, the inclination angle θ of the side surface of the insertion layer 170 may range from 5° to 70°.

The inclined portion 1231 of the piezoelectric layer 123 is formed along the inclined surface L of the insertion layer 170, and thus may be formed at the same inclination angle as that of the inclined surface L of the insertion layer 170. Accordingly, the inclination angle of the inclined portion 1231 may range from 5° to 70°, similarly to the inclined surface L of the insertion layer 170. An inclination angle of the second electrode 125 stacked on the inclined surface L of the insertion layer 170 may also range from 5° to 70°, similarly to the inclined surface L of the insertion layer 170.

The insertion layer 170 may be formed of a dielectric such as silicon oxide (SiO₂), aluminum nitride (AIN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), etc., but may be formed of a material different from that of the piezoelectric layer 123.

For example, the insertion layer 170 may include a metal material, may be formed of an aluminum alloy material containing scandium (Sc), and may be formed of a SiO₂ thin film in which nitrogen (N) or fluorine (F) is included.

The resonant portion 120 may be spaced apart from the substrate 110 through the cavity C, which is formed as an empty space. The cavity C may be formed by removing a portion of the sacrificial layer 140 by supplying an etching gas (or an etching solution) to an inflow hole (H of FIG. 1) during a manufacturing process of the acoustic resonator 100.

The protective layer 160 may be disposed on a surface of the bulk acoustic resonator 100 to protect the bulk acoustic resonator 100 from the outside. The protective layer 160 may be disposed on the surface formed by the second electrode 125 and the bent portion 123b of the piezoelectric layer 123.

The first electrode 121 and the second electrode 125 may extend to an outer side of the resonant portion 120. In addition, the first metal layer 180 and the second metal layer 190 may be disposed on an upper surface of the extension portion.

The first metal layer 180 and the second metal layer 190 may be formed of any one of gold (Au), gold-tin (Au-Sn) alloy, copper (Cu), copper-tin (Cu-Sn) alloy, aluminum (Al), and an aluminum alloy. Here, the aluminum alloy may be an aluminum-germanium (Al-Ge) alloy or an aluminum-scandium (Al-Sc) alloy.

The first metal layer 180 and the second metal layer 190 may function as connection interconnections electrically connecting the first and second electrodes 121 and 125 of the bulk acoustic resonator 100 on the substrate 110 to electrodes of another bulk acoustic resonator disposed adjacent thereto.

The first metal layer 180 may penetrate through the protective layer 160 and may be bonded to the first electrode 121.

In addition, in the resonant portion 120, the first electrode 121 may have an area larger than that of the second electrode 125, and the first metal layer 180 may be formed on a peripheral portion of the first electrode 121.

Accordingly, the first metal layer 180 is disposed along the circumference of the resonant portion 120 and is disposed to surround the second electrode 125. However, the disclosure is not limited to such a configuration.

At least a portion of the protective layer 160 positioned on the resonant portion 120 may be in contact with the first metal layer 180 and the second metal layer 190. Since the first metal layer 180 and the second metal layer 190 may be formed of a metal material having high thermal conductivity and a large volume, a heat dissipation effect may be large.

Therefore, the protective layer 160 may be connected to the first metal layer 180 and the second metal layer 190 so that heat generated in the piezoelectric layer 123 may be rapidly transferred to the first metal layer 180 and the second metal layer 190 via the protective layer 160.

For example, at least a portion of the protective layer 160 may be disposed below the first metal layer 180 and the second metal layer 190 and may be inserted between the first metal layer 180 and the piezoelectric layer 123, and between the second metal layer 190, the second electrode 125, and the piezoelectric layer 123.

Referring to FIG. 4, the resonant portion 120 may include a central portion (zone A), a reflective portion (zone B), a reflection control portion (zone C), and an outer portion (zone D).

Since the central portion (zone A) may have a structure in which the first electrode 121, the piezoelectric layer 123, and the second electrode 125 vertically overlap one another, the central portion (zone A) may be effective to vibrate vertically. Accordingly, most of the energy of an RF signal applied to the first electrode 121 and/or the second electrode 125 may correspond to the vertical vibration energy in the central portion (zone A).

However, the resonant portion 120 may not be vertically perfectly symmetric, and a vertical asymmetry factor in the resonant portion 120 may increase a ratio of converting energy of the RF signal into a lateral wave. Since the lateral wave may be energy leaking laterally from the resonant portion 120, energy loss in the process of the RF signal passing between the first electrode 121 and the second electrode 125 may increase as the lateral wave component increases.

In view of a circuit of the bulk acoustic resonator 100, it may be interpreted that there are a plurality of signal paths in parallel with each other connected to a terminal to which an RF signal is applied. One of the plurality of signal paths may be a vertical path (e.g., the central portion (zone A)) in which energy is converted and inversely converted according to vertical vibration, and the other of the plurality of signal paths may be a horizontal path (e.g., between the central portion (zone A) and a side portion) leaking with a lateral wave. A ratio between a component passing through the vertical path and a component passing through the horizontal path in the energy of the RF signal may be based on a ratio between acoustic impedance of the vertical path and acoustic impedance of the horizontal path.

Therefore, since the acoustic impedance of the reflective portion (zone B) adjacent to the central portion (zone A) is higher than the acoustic impedance of the central portion (zone A), the ratio of converting the energy of the RF signal into the lateral wave component may be lowered. Accordingly, energy loss of the RF signal in the resonant portion 120 may be reduced.

According to an analysis, since the acoustic impedance of the reflective portion (zone B) adjacent to the central portion (zone A) is higher than the acoustic impedance of the central portion (zone A), the reflective portion (zone B) may more efficiently reflect the lateral wave component, and thus, energy leaking in the process of the RF signal passing between the first electrode 121 and the second electrode 125 may be reduced.

An upper surface of the second electrode 125 in the reflective portion (zone B) may rise, relative to the central portion (zone A), to surround the central portion (zone A). Alternatively, a distance between the first electrode 121 and the second electrode 125 in the reflective portion (zone B) may be increased. For example, the upper surface of the second electrode 125 in the reflective portion (zone B) may rise at least partially as the piezoelectric layer 123 and the second electrode 125 is raised by the insertion layer 170. However, the present disclosure is not limited to this configuration.

Accordingly, in terms of a direction in which the lateral wave passes through the reflective portion (zone B) (e.g., a direction oblique to the horizontal direction), overall acoustic pressure in the reflective portion (zone B) of the resonant portion 120 may be higher than that in the central portion (zone A) due to the first electrode 121 and/or the second electrode 125, and may be further higher due to the insertion layer 170. Since acoustic pressure may be proportional to acoustic impedance, the reflective portion (zone B) may have acoustic impedance higher than that of the central portion (zone A), and the lateral wave component itself may be reduced or lateral leakage of the lateral wave may be reduced.

The acoustic impedance may be defined by a ratio obtained by dividing an acoustic transmission area by specific acoustic impedance, and the acoustic transmission area may be larger as a thickness of the corresponding portion increases. Therefore, assuming that an average non-acoustic impedance of a combination structure of the resonant portion 120 and the protective layer 160 in the reflective portion (zone B) is fixed, the acoustic impedance in the reflective portion (zone B) may increase as a thickness of the combination structure of the resonant portion 120 and the protective layer 160 is reduced.

Since the second electrode 125 may include a material (e.g., molybdenum) having a relatively high acoustic pressure for the efficiency of vertical vibration of the resonant portion 120, the specific acoustic impedance of the second electrode 125 may be higher than that of the piezoelectric layer 123, the protective layer 160, and the insertion layer 170.

Therefore, if the thickness of at least one of the piezoelectric layer 123, the protective layer 160, and the insertion layer 170 is reduced to reduce the thickness of the combination structure of the resonant portion 120 and the protective layer 160, the average non-acoustic impedance of the combination structure of the resonant portion 120 and the protective layer 160 may be increased, and thus, acoustic impedance in the reflective portion (zone B) may be higher.

Here, the piezoelectric layer 123 and/or the insertion layer 170 has a structure raising the upper surface of the second electrode 125 in the reflective portion (zone B) or increasing a distance between the first electrode 121 and the second electrode 125, a change in the thickness of the piezoelectric layer 123 and/or the insertion layer 170 may affect the overall acoustic pressure in the reflective portion (zone B).

Therefore, the reduction in the thickness of the protective layer 160 may more significantly affect the reduction in acoustic impedance of the combination structure of the resonant portion 120 and the protective layer 160, compared to a reduction in the thickness of the piezoelectric layer 123 and/or the insertion layer 170.

The protective layer 160 may cover the central portion (zone A) and the reflective portion (zone B) together, and an upper surface of the portion covering the reflective portion (zone B) in the protective layer 160 may be more gently inclined than the upper surface of the reflective portion (zone B) of the second electrode 125. An inclination angle θ2 of the upper surface covering the reflective portion (zone B) in the protective layer 160 may be less than an inclination angle (which may be the same as θ) of the upper surface of the reflective portion (zone B) of the second electrode 125.

Accordingly, since the thickness of the portion covering the reflective portion (zone B) in the protective layer 160 may be harmoniously reduced, the reflective portion (zone B) may have higher acoustic impedance than the central portion (zone A) and may reduce the lateral wave component itself or reduce lateral leakage of the lateral wave.

Since the inclination angle (which may be the same as θ) of the upper surface of the reflective portion (zone B) of the second electrode 125 may range from 5° to 70°, the upper and lower surfaces of the second electrode 125 in the reflective portion (zone B) may be inclined with respect to the upper and lower surfaces of the second electrode 125 in the central portion (zone A). In addition, the inclination angle θ2 of the upper surface covering the reflective portion (zone B) in the protective layer 160 may be greater than 0° and less than 70°, and the upper surface covering the reflective portion (zone B) in the protective layer 160 may rise, relative to the upper surface of the portion covering the central portion (zone A).

The reflection control portion (zone C) may surround the reflective portion (zone B), and the outer portion (zone D) may surround the reflection control portion (zone C). Since the reflection control portion (zone C) and/or the outer portion (zone D) may provide a difference in acoustic impedance between adjacent portions, the lateral wave reflection efficiency of the bulk acoustic resonator 100 may be improved.

The second electrode 125 may not be disposed in the reflection control portion (zone C) and the outer portion (zone D). Since the second electrode 125, having relatively high non-acoustic impedance, is not disposed in the reflection control portion (zone C) and the outer portion (zone D), the acoustic impedance of the reflection control portion (zone C) may be higher than that of the reflection portion (zone B). The reflection control portion (zone C) may become smaller or may be omitted as the second electrode 125 becomes larger horizontally.

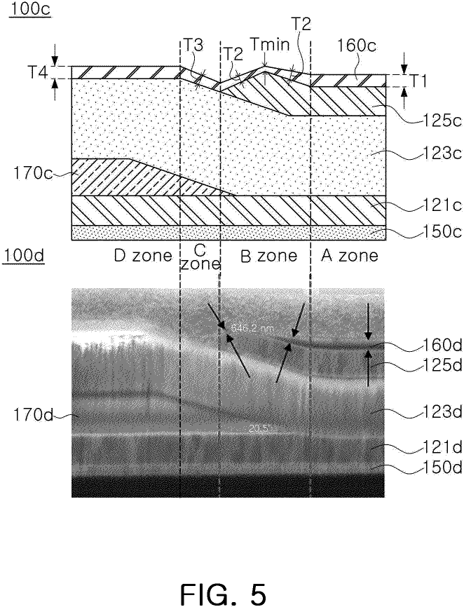

FIG. 5 is a cross-sectional view and a photograph illustrating a structure capable of increasing reflection performance of a lateral acoustic wave of a bulk acoustic resonator, according to an exemplary embodiment.

Referring to FIG. 5, bulk acoustic resonators 100c and 100d, according to embodiments, may include first electrodes 121c and 121d, piezoelectric layers 123c and 123d, second electrodes 125c and 125d, and protective layers 160c and 160d, respectively, and may further include insertion layers 170c and 170d and membrane layers 150c and 150d, respectively.

A thickness T2 covering the reflective portion (zone B) in the respective protective layers 160c and 160d of the bulk acoustic resonators 100c and 100d may be less than a thickness T1 covering the central portion (zone A). For example, a ratio obtained by dividing the thickness T2 covering the reflective portion (zone B) in the protective layers 160c and 160d by the thickness T1 covering the central portion may be less than a ratio obtained by dividing the thickness in the reflective portion (zone B) of the second electrodes 125c and 125d by the thickness in the central portion (zone A).

Accordingly, the reflective portion (zone B) may have a higher acoustic impedance than the central portion (zone A), and the lateral wave component itself may be reduced or lateral leakage of the lateral wave may be reduced.

Here, a reference direction of the thicknesses T1, T2, T3, and T4 of the protective layers 160c and 160d may be defined as a direction, perpendicular to the upper surface of the corresponding portion, and may also be perpendicular to the direction in which the lateral wave passes through the corresponding portion. For example, the thicknesses T1, T2, T3, and T4 and the inclination angles θ and θ2 may be measured by analysis using any one or any combination of any two or more of a transmission electron microscope (TEM), an atomic force microscope (AFM), a scanning electron microscope (SEM), an optical microscope, and a surface profiler.

Since the upper surface of the protective layers 160c and 160d covering the reflective portion (zone B) may be more gently inclined than the upper surface of the reflective portion (zone B) of the second electrodes 125c and 125d, the protective layer 160c and 160d may have a minimum thickness Tmin at an edge positioned in a portion covering the reflective portion (zone B).

For example, the protective layers 160c and 160d may further cover the reflection control portion (zone C) and/or the outer portion (zone D) and may continuously cover the reflective portion (zone B) and the central portion (zone A).

The thickness T2 of portions of the protective layers 160c and 160d covering the reflective portion (zone B) may be less than the thickness T4 of portions of the protective layers 160c and 16d covering the outer portion zone D. Accordingly, the difference in acoustic impedance between the reflective portion (zone B) and the outer portion zone D may become larger, and thus the lateral wave reflection efficiency may be further improved.

For example, a thickness difference of the protective layers 160c and 160d may be implemented by uniformly depositing the protective layers 160c and 160d in the central portion (zone A), the reflective portion (zone B), the reflection control portion (zone C), and the outer portion (zone D) and then locally etching the reflective portion (zone B). For example, depending on material etching characteristics or size of the protective layers 160c and 160d, at least one of physical (e.g., dry etching, fine particle collision) etching, chemical (e.g., wet etching, an etching gas used to form a cavity is used) etching, and reactive ion etching may be selectively used as the local etching. However, the etching of the reflective portion (zone B) is not limited to the foregoing examples.

For example, the smoothness of the upper surfaces of the protective layers 160c and 160d may be implemented by etching of the protective layers 160c and 160d or annealing before and after frequency trimming, or may be implemented by adjusting an area of the frequency trimming.

The frequency trimming refers to finely etching an area including the central portion (zone A) of the protective layers 160c and 160d in order to more precisely match the resonant frequency and/or antiresonant frequency of the bulk acoustic resonator to a desired frequency. That is, the protective layers 160c and 160d may not only protect the bulk acoustic resonators 100c and 100d, but also contribute to frequency fine adjustment.

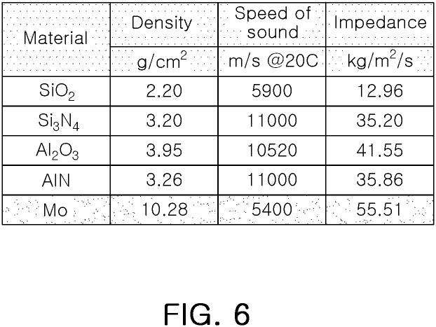

FIG. 6 is a diagram illustrating specific acoustic impedance of a material that may be contained in a protective layer and a material that may be contained in an electrode.

Referring to FIG. 6, impedance corresponding to specific acoustic impedance may be calculated as a product of a density corresponding to an acoustic pressure and a speed of sound.

The specific acoustic impedance of SiO2, Si₃N₄, Al₂O₃, and AIN may each be lower than that of molybdenum (Mo). Since the protective layer may contain any one or any combination of any two or more of SiO2, Si₃N₄, Al₂O₃, and AIN and the second electrode may contain molybdenum (Mo), the specific acoustic impedance of the protective layer may be lower than that of the second electrode.

Since the specific acoustic impedance of the piezoelectric layer may also be lower than that of the second electrode, the protective layer may contain the same material as the piezoelectric material contained in the piezoelectric layer.

As the thickness of the protective layer covering the reflective portion decreases, the overall thickness of the combination structure of the resonant portion and the protective layer may decrease and the overall acoustic pressure of the combined structure may increase. Since the acoustic impedance may be proportional to acoustic pressure and may be inversely proportional to a transmission area (or thickness), acoustic impedance of the combination structure in the reflective portion having a protective layer having a relatively small thickness or having an upper surface that is more gently inclined in an upper surface thereof may be higher than the acoustic impedance of the combination structure in the central portion.

A first bulk acoustic resonator including a central portion having a horizontal area of 50 µm square and a second bulk acoustic resonator including a central portion having a horizontal area of 70 µm square were manufactured and tested. The insertion loss, lateral wave reflection characteristics, and Kt²were 0.055 dB, 36.63 dB, and 7.29%, respectively, when the thickness of a portion of the protective layer of the first bulk acoustic resonator covering the reflective portion was less than the thickness of a portion of the protective layer covering the central portion. The insertion loss, lateral wave reflection characteristics, and Kₜ² were 0.038 dB, 33.78 dB, and 7.59%, respectively, when the thickness of the portion of the protective layer of the second bulk acoustic resonator covering the reflective portion was less than the thickness of the portion of the protective layer covering the central portion. The insertion loss may be lower than that of the first and second bulk acoustic resonators having a constant thickness of the protective layer, the lateral wave reflection characteristic may be higher than that of the first and second bulk acoustic resonators having a constant thickness of the protective layer, and Kₜ² may be higher than that of the first and second bulk acoustic resonators having a constant thickness of the protective layer.

Since a difference between the resonant frequency and the antiresonant frequency of the bulk acoustic resonator may increase as Kₜ² is higher, the thickness of the portion of the protective layer covering the reflective portion may be less than the thickness of the portion of the protective layer covering the central portion, to increase the difference between the resonant frequency and the antiresonant frequency of the bulk acoustic resonator.

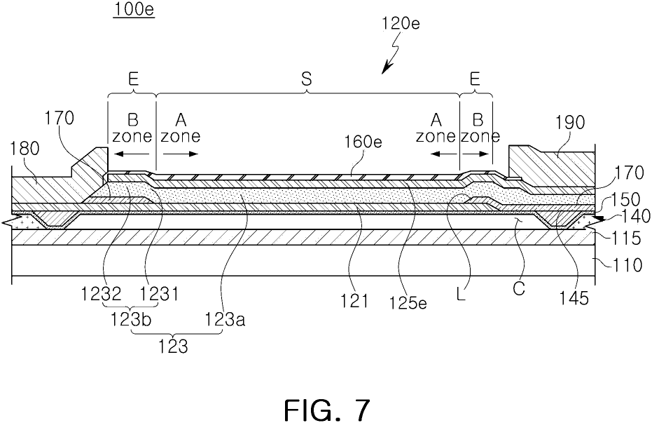

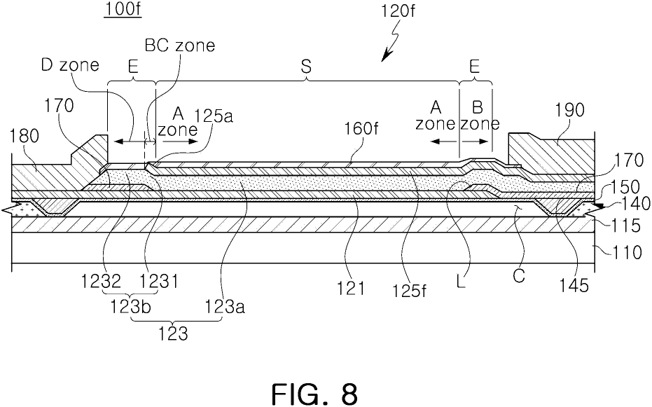

FIGS. 7 and 8 are cross-sectional views illustrating a modified structures of a second electrode of a bulk acoustic resonator, according to embodiments.

Referring to FIG. 7, a second electrode 125e of a bulk acoustic resonator 100e, according to an embodiment, may be disposed on the entire upper surface of the piezoelectric layer 123 in a resonant portion 120e. Accordingly, at least a portion of the second electrode 125e may be formed on the extension portion 1232 as well as the inclined portion 1231 of the piezoelectric layer 123.

Although the second electrode 125e may be horizontally larger than the second electrode 125 of FIGS. 1 to 5, the thickness of the portion of a protective layer 160e covering the reflective portion (zone B) may be thinner than the thickness of the portion of the protective layer 160 covering the central portion (zone A). Accordingly, a difference in acoustic impedance between the reflective portion (zone B) and the central portion (zone A) may become larger.

Referring to FIG. 8, a second electrode 125f of a bulk acoustic resonator 100f having a resonant portion 120f, according to an embodiment, may be horizontally slightly larger than the second electrode 125 of FIGS. 1 to 5. Accordingly, an integrated reflective portion (BC zone) in which the reflective portion and the reflection control portion of FIGS. 4 and 5 are integrated may be formed.

Accordingly, the upper surface of the second electrode 125f may rise higher in the integrated reflective portion (BC zone), and the upper surface of a protective layer 160f may rise more gently in the integrated reflective portion (BC zone) or may not rise. Accordingly, a difference in acoustic impedance between the integrated reflective portion (BC zone) and the central portion (zone A) may become larger.

As described above, the bulk acoustic resonator, according to an exemplary embodiment, may be modified into various shapes as needed.

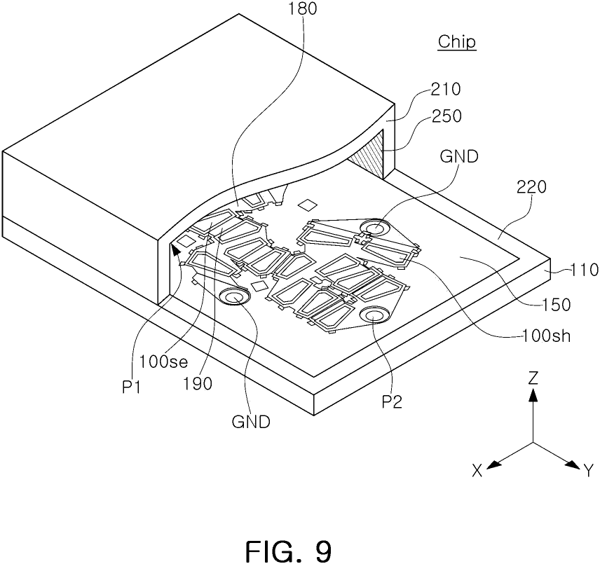

FIG. 9 is a perspective view illustrating a filter including a bulk acoustic resonator, according to an embodiment.

Referring to FIG. 9, bulk acoustic resonators 100se and 100sh may include at least one series bulk acoustic resonator 100se and/or at least one shunt bulk acoustic resonator 100sh.

The at least one series bulk acoustic resonator 100se may be electrically connected between a first port P1 and a second port P2, and the at least one shunt bulk acoustic resonator 100sh may be electrically connected between the series bulk acoustic resonator 100se and a ground port GND.

Depending on a resonant frequency and/or antiresonant frequency relationship between the at least one series bulk acoustic resonator 100se and the at least one shunt bulk acoustic resonator 100sh, a filter chip may be implemented as a bandpass filter or a notch filter.

Since the bulk acoustic resonators 100se and 100sh may reduce the lateral wave itself or reduce lateral leakage of the lateral wave, energy loss made when the RF signal passes through each of the bulk acoustic resonators 100se and 100sh may be reduced, and thus, an overall insertion loss and/or reflection loss of the filter (chip) may be reduced. In addition, since spurious frequencies near the resonant frequency according to the lateral wave may be reduced, an attenuation characteristic at the end of the bandwidth of the filter (chip) may also become sharper.

Each of the first port P1, the second port P2, and the ground port GND may have a vertical electrical path penetrating through the substrate 110 and may be electrically connected to a printed circuit board (PCB) that may be disposed on a lower surface of the filter (chip).

The bulk acoustic resonators 100se and 100sh may be accommodated in a cap 210, between the substrate 110 and the cap 210, and a bonding member 220 may bond the cap 210 to the substrate 110 and/or the membrane layer 150. For example, the bonding member 220 may include a eutectic coupling structure including a conductive ring or an anodic coupling structure.

Depending on the design, a shield layer 250 may be disposed on the entire or most of a lower surface and/or inner surface of the cap 210 and may be connected to the bonding member 220.

As set forth above, the bulk acoustic resonator according to embodiments disclosed herein may reduce the occurrence of lateral waves in the resonance and/or antiresonance process or reduce lateral leakage of the lateral waves, thereby reducing energy loss.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic resonator, comprising:
a substrate;
a protective layer; and
a resonant portion including a piezoelectric layer, a first electrode disposed between the piezoelectric layer and the substrate, and a second electrode disposed between the piezoelectric layer and the protective layer,
wherein the protective layer covers a central portion of the resonant portion and a reflective portion surrounding the central portion and formed in a region in which an upper surface of the second electrode rises relative to the central portion, , and
wherein an upper surface of a portion of the protective layer covering the reflective portion is more gently inclined than the upper surface of a portion of the second electrode in the reflective portion.

2. The bulk acoustic resonator of claim 1, wherein the protective layer includes any one or any combination of any two or more of SiO₂, Si₃N₄, Al₂O₃, and AIN, or includes a piezoelectric material included in the piezoelectric layer.

3. The bulk acoustic resonator of claim 1, wherein a specific acoustic impedance of the protective layer is lower than a specific acoustic impedance of the second electrode, and
wherein an acoustic impedance of a combination structure of the resonant portion and the protective layer in the reflective portion is higher than an acoustic impedance of the combination structure in the central portion.

4. The bulk acoustic resonator of claim 1, wherein the upper surface of the portion of the protective layer covering the reflective portion in the protective layer rises relative to a portion of the protective layer covering the central portion.

5. The bulk acoustic resonator of claim 1, wherein the protective layer continuously covers the reflective portion and an outer portion disposed outside of the reflective portion, and
wherein the second electrode is not disposed at the outer portion.

6. The bulk acoustic resonator of claim 1, wherein the upper surface of the portion of the second electrode in the reflective portion and a lower surface of the portion of the second electrode in the reflective portion is slanted with respect to an upper surface of a portion of the second electrode in the central portion and a lower surface of a portion of the second electrode in the central portion.

7. The bulk acoustic resonator of claim 1, wherein the upper surface of the portion of the second electrode in the reflective portion rises as a distance between the first electrode and the second electrode increases.

8. The bulk acoustic resonator of claim 1, further comprising:
an insertion layer partially disposed in the resonant portion,
wherein the upper surface of the portion of the second electrode in the reflective portion rises as at least a part of the piezoelectric layer and the second electrode is uplifted by the insertion layer.

9. The bulk acoustic resonator of claim 1, wherein a thickness of the portion of the protective layer covering the reflective portion is less than a thickness of a portion of the protective layer covering the central portion.

10. A bulk acoustic resonator, comprising:
a substrate;
a protective layer; and
a resonant portion including a piezoelectric layer, a first electrode disposed between the piezoelectric layer and the substrate, and a second electrode disposed between the piezoelectric layer and the protective layer,
wherein the protective layer covers a central portion of the resonant portion and a reflective portion extending a spacing distance between the first electrode and the second electrode, relative to the central portion, and surrounding the central portion, and
wherein a thickness of a portion of the protective layer covering the reflective portion is less than a thickness of a portion of the protective layer covering the central portion.

11. The bulk acoustic resonator of claim 10, further comprising:
an insertion layer partially disposed in the resonant portion,
wherein an upper surface of a portion of the second electrode in the reflective portion rises as at least a portion of the piezoelectric layer and the second electrode is uplifted by the insertion layer.

12. The bulk acoustic resonator of claim 10, wherein
the protective layer continuously covers the reflective portion and an outer portion disposed outside of the reflective portion, and
wherein a thickness of the portion of the protective layer covering the reflective portion is less than a thickness of a portion of the protective layer covering the outer portion.

13. The bulk acoustic resonator of claim 10, wherein an upper surface of the portion of the protective layer covering the reflective portion rises relative to an upper surface of the portion of the protective layer covering the central portion.

14. The bulk acoustic resonator of claim 10, wherein a ratio of a thickness of the portion of the protective layer covering the reflective portion to a thickness of the portion of the protective layer covering the central portion is less than a ratio of a thickness of the second electrode in the reflective portion to a thickness of the second electrode in the central portion.

15. The bulk acoustic resonator of claim 10, wherein the thickness of the portion of the protective layer covering the reflective portion is less than a thickness of the portion of the protective layer covering the central portion, such that a difference between a resonance frequency and an antiresonance frequency of the bulk acoustic resonator is increased.

16. The bulk acoustic resonator of claim 10, wherein the protective layer includes any one or any combination of any two or more of SiO₂, Si₃N₄, Al₂O₃, and AIN or includes a piezoelectric material included in the piezoelectric layer.

17. A bulk acoustic resonator, comprising:
a substrate;
a protective layer; and
a resonant portion including a piezoelectric layer, a first electrode disposed between the piezoelectric layer and the substrate, and a second electrode disposed between the piezoelectric layer and the protective layer,
wherein the protective layer covers a central portion of the resonant portion and a reflective portion surrounding the central portion and formed in a region in which an upper surface of the second electrode is elevated relative to the central portion, and
wherein an upper surface of a portion of the protective layer covering the reflective portion is inclined less than the upper surface of a portion of the second electrode in the reflective portion, and a thickness of the portion of the protective layer covering the reflective portion is less than each of a thickness of a portion of the protective layer covering the central portion and a thickness of a portion of the protective layer covering an outer portion of the bulk acoustic resonator disposed outside of the reflective portion.

18. The bulk acoustic resonator of claim 17, a ratio of a thickness of the portion of the protective layer covering the reflective portion to a thickness of the portion of the protective layer covering the central portion is less than a ratio of a thickness of the second electrode in the reflective portion to a thickness of the second electrode in the central portion.

19. The bulk acoustic resonator of claim 17, wherein a specific acoustic impedance of a material of the protective layer is lower than a specific acoustic impedance of a material of the second electrode.

20. The bulk acoustic resonator of claim 17, wherein the second electrode is not disposed in the outer portion.
